(19) United States
(12) Patent Application Publication
(10) Pub. No.: US 2002/0145187 A1
(43) Pub. Date: Oct. 10, 2002

(54) Package and a shield for an optical chip

(76) Inventors: Stephen Mark Baxter, Bicester (GB); Andrew Cornish, Kempsford (GB)

Correspondence Address: FULBRIGHT & JAWORSKI L.L.P., Michael J. Fogarty, III, Suite 2800, 2200 Ross Avenue, Dallas, TX, 75201, US

(21) Appl. No.: 10/078,244

(22) Filed: Feb. 19, 2002

(30) Foreign Application Priority Data
Feb. 19, 2001 (GB) 0104038.5

(51) Int. Cl. H01L 23/02

(52) U.S. Cl. 257/678

(57) ABSTRACT

A package (10) for receiving an optical chip (20) having a light source (31) to emit light and a circuit element (33) whose performance is adversely affected by the incidence thereon of stray light from the light source. The package includes a barrier element (81) which is adapted to absorb light emitted by the light source and which is so dimensioned and arranged as to be positioned between the light source and the circuit element when the optical chip is received in the package. The barrier element may be on a shield (50) forming a part of the package.

### RELATED APPLICATION

This application claims priority from UK patent application No. 0104038.6 filed an Feb. 19, 2001, the entire original content of which is herein incorporated by reference.

### FIELD OF THE INVENTION

The present invention relates to a package and a shield for an optical chip.

### BACKGROUND OF THE INVENTION

One example of an optical chip is an optical transceiver. An optical transceiver typically comprises a substrate of silicon mounted on an insulator (silicon-on-insulator chip), a laser diode and a photodiode located on an upper surface of the silicon substrate, and optical waveguides formed an the upper surface for respectively transmitting light from, and to, the laser diode and the photodiode. A transimpedance amplifier is integrated on the insulator to increase the sensitivity of the photodiode. Optical fibres are seated in V-shaped grooves on the upper surface of the substrate so as to communicate with the waveguides.

The optical transceiver is mounted in a package to provide the transceiver with a hermetic environment and electrical shielding. As importantly, the package serves to couple the optical transceiver to a printed circuit board. One such package is made Known in WO00/02079 (Bookham Technology Limited/Yeandle et al).

Optical transceivers are used for bi-directional communication in access network applications, such as fibre to the curb or fibre to the cabinet in telecommunications networks. Optical transceivers are designed to work over a temperature range of −40° C. to 85° C. thereby making them suitable for applications in uncontrolled environments.

The efficiency of optical transceivers is adversely affected by optical cross-talk between the laser diode and the photodiode. Optical cross-talk occurs due to the incidence of stray light from the laser diode an the photodiode. The stray light may travel from the laser diode to the photodiode either in the air (super-substrate), directly or by reflection, or through the silicon substrate (intra-substrate).

To reduce super-substrate optical cross-talk it is known to adhere a ceramic block which absorbs stray light on the upper surface of the silicon substrate between the diodes and to provide the package in which the transceiver is housed with a light absorbing, plastic isolation lid. A problem with this approach is that the ceramic block is liable to become detached from the substrate and that the manufacturing process is complicated.

Optical cross-talk is not restricted to transceivers but is a general problem in optical chips having a light source, such as a light emitting diode, and a circuit element whose performance is adversely affected by the incidence thereon of stray light from the light source, e.g. a light sensor, another light source, a monitor, etc.

The present invention proposes to provide novel means for reducing optical cross-talk between the light source and the circuit element.

### SUMMARY OF THE INVENTION

According to the present invention there is provided a package for receiving an optical chip having a light source to emit light and a circuit element whose performance is adversely affected by the incidence thereon of stray light from the light source, the package including a barrier element which is adapted to absorb light emitted by the light source and which is so dimensioned and arranged as to be positioned between the light source and the circuit element when the optical chip is received in the package.

As an example, the package may, in use, define a cavity which receives the optical chip with the barrier element depending from a boundary surface of the cavity.

The optical chip may have a substrate with a surface on which the light source and the circuit element are positioned and the barrier element may be so dimensioned and arranged as to be positioned on the substrate surface when the optical chip is received in the package.

The package may have a movable element which has a surface from which the barrier element depends. The movable element surface may present the cavity boundary surface when the movable element is moved from a first position to a second position. The movable element may be a detachable element of the package. The movable element may be an internal cover which in use covers at least a part of the surface of the optical chip when the optical chip is received in the package. Alternatively, the movable element may be an outer lid.

In another embodiment, the barrier element is presented by a fixed boundary surface of the package cavity.

According to the invention there is also provided a package according to the invention which includes the optical chip.

According to the invention there is further provided a shield for reducing optical cross-talk in an optical circuit device with a light source to emit light and a circuit element whose performance is adversely affected by the incidence thereon of stray light from the light source, the shield having a body part which is adapted to be secured to the optical circuit device and a barrier part depending from the body part which is adapted to absorb light emitted by the light source, the shield being so constructed and arranged that the barrier part is positioned between the light source and the circuit element when the body part is secured to the optical circuit device.

The light source and the circuit element may be positioned on a surface of a substrate in which case the shield may be so constructed and arranged that the barrier part is positioned on the substrate surface when the body part is secured to the optical circuit device.

The optical circuit device may be an optical chip or a package including an optical chip.

According to the present invention there is yet further provided a combination of an optical circuit device having an optical chip having a light source to emit light and a circuit element whose performance is adversely affected by the incidence thereon of stray light from the light source and a shield according to the invention. The optical circuit device may have a package according to the invention with the optical chip being received in the package and the shield taking the form of the movable element of the package.

Preferably, the barrier element/part is in the form of a post. Alternatively, the barrier element/part may be in the form of an elongate wall. The barrier element/part may be sized to be received in a structural discontinuity in the substrate surface, preferably with a first portion received in the structural discontinuity and a second portion being located above the substrate surface.

The barrier element/part may be formed from a composition which contains carbon. The barrier element/part may additionally, or alternatively, be formed from a composition which contains a plastics material, for example a homopolymer, a copolymer or a blend of a thermoplastic polyester such as poly(butylene terephthalate) or a mixture thereof. Preferably, the barrier element is made from a carbon loaded thermoplastic polyester composition. The movable element or body part may be made from the same composition as the barrier element/part.

The light source may be a light emitting diode, such as a laser diode. The circuit element may be a light source, a light sensor, for example a light sensor diode such as a photodiode, or a monitor etc.

The barrier element/part is preferably an integrally formed part of the package, e.g. of the boundary surface of the cavity, or of the shield.

Embodiments of the present invention will now be described with reference to the accompanying Figures of drawings.

### BRIEF DESCRIPTION OF THE DRAWINGS

FIG. 1 is a perspective view of a base of a package housing an integrated optical chip and a shield in accordance with the present invention to be mounted in the base;

FIG. 2 is a perspective, partial view of the integrated optical chip;

FIG. 3A is a view of the underneath of the shield from one side and towards one end;

FIG. 3B is a plan view of the shield;

FIG. 3C is an underneath plan view of the shield;

FIG. 3D is a cross-sectional view along line 3D-3D in FIG. 3C;

FIG. 3E is an end view of the shield along arrow A in FIG. 3C;

FIG. 3F is an end view of the shield along arrow B in FIG. 3C;

FIG. 3G is a side view of the shield;

FIG. 4 corresponds to FIG. 1 with the shield mounted in the base;

FIG. 5 is a perspective view, partly broken away and partly in section, showing the package assembled with the shield and an outer lid; and

FIG. 6 is a view similar to FIG. 5 showing an alternative embodiment of the invention.

### DETAILED DESCRIPTION OF THE EXEMPLARY EMBODIMENTS

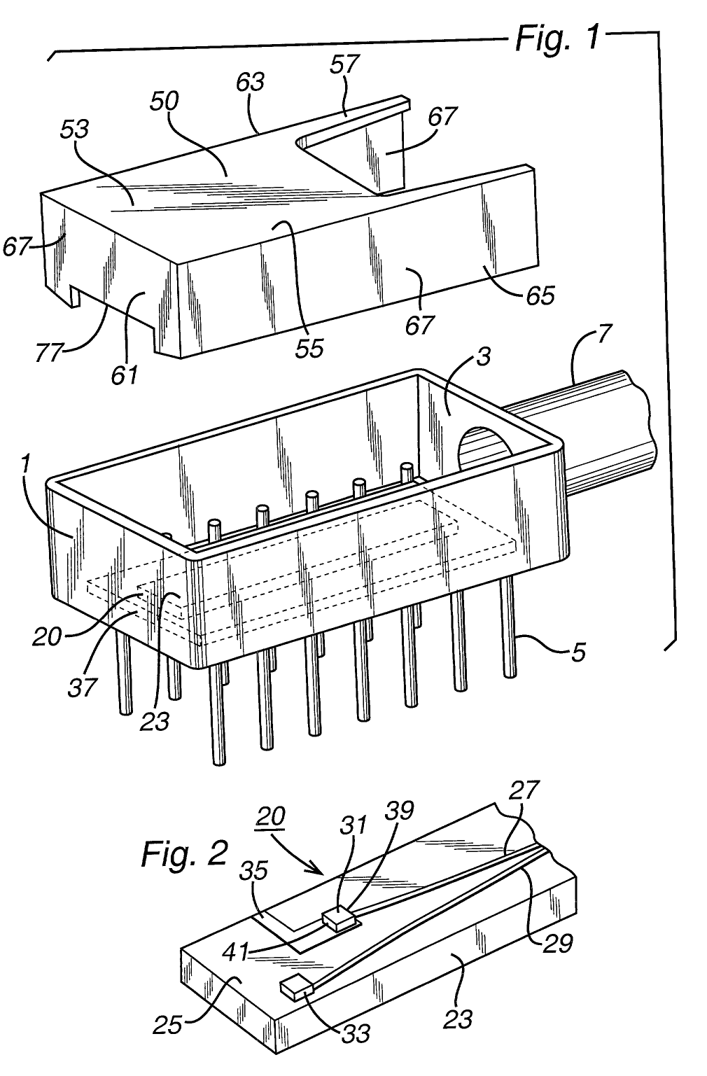

In FIGS. 1, 4 and 5 there is shown a base 1 of a package 10 for an integrated optical chip 20. The base 1 has a recess 3, to the floor of which the optical chip 20 is coupled, and includes electrically conducting pins 5 extending into the recess 3 for connection to a printed circuit board for conducting electricity to, and from, the opto-electronic components of the chip 20. The base 1 also has a tube 7 into which an optical fibre cable (not shown) can be inserted to be held in a ferrule (not shown) in the tube 7. A central optical fibre (not shown) then extends from the cable for attachment to the chip 20. Further details on the connection of the optical fibre cable to the package 10, as well as other details an the general principle of the package 10, will be understood by reference to WO00/02079 supra, the contents of which are hereby incorporated by reference.

Turning now to FIG. 5, the package 10 further includes a lid 9 to cover the recess 3. The base 1 and lid 9 are made from KOVAR (Ni—Co—Fe) to provide electrical shielding for the optical chip 20. In addition to its electrical shielding function, the package 10 functions to hermetically seal the chip 20.

The integrated optical chip 20 in the package 10 in this embodiment is an optical transceiver, The optical transceiver 20 is shown in FIG. 2 from which it can be seen that the transceiver 20 has a silicon substrate 23 having an upper surface 25 on which are formed optical waveguides 27, 29 in a conventional manner. Located on the upper surface 25 of the substrate 23 are a laser diode 31 and a photodiode 337 each being coupled with a different optical waveguide 27, 29. The substrate upper surface 25 is also provided with an electrical trigger 35 for the laser diode 31 As shown in FIG. 5, the chip 20 is mounted on a ceramic insulator 37.

In operation, the laser diode 31 emits light from both a front surface 39 and a rear surface 41. While the light emitted from the front surface 39 is directed forwardly into the associated waveguide 27, the light emitted from the rear surface 41 can give rise to optical cross-talk between the diodes 31, 33 if it is not absorbed or attenuated. In addition, light emitted from the front surface 39 which is not coupled into the associated waveguide 27 can give rise to optical cross-talk.

Referring now to FIGS. 1 and 3 to 6, to reduce optical cross-talk between the diodes 31, 33, a light absorbing shield 50 is mounted in the package 10 between the optical transceiver 20 and the lid 9. The shield 50 is made of a material which is able to absorb or attenuate the light emitted by the rear surface 41 of the laser diode 31 and any other superfluous light emitted by the laser diode 31 (hereinafter “stray light”). The wavelength of the light emitted by the laser diode 31 is in the range of 1260-1360 nm or 1500-1600 nm. The light absorbing material is a composition which preferably contains carbon, for example carbon black. The light absorbing material also preferably contains a plastics material, more preferably a homopolymer or a copolymer or a blend of a thermoplastic polyester such as poly(butylene terephthalate) or a mixture thereof Most preferably, the shield 50 is injection moulded from a composition which consists essentially of carbon loaded poly(butylene terephthalate) (Cotswold Eng. Ltd.). A carbon loaded poly(butylene terephthalate) composition is chemically inert over a temperature range of at least −40° C. to 100° C. and does not outgas hydrocarbons under extended temperatures or lifetimes, for example to comply with the residual gas analysis (RCA) requirements of the telecommunications standard Telcordia GR-468-CORE.

The shield 50 has a body 51 comprising a cover plate 53 which, in use, covers a part of the optical transceiver 20. A rear portion 55 of the cover plate 53 covers a rear portion of the chip which includes the diodes 31, 33. A forward portion 57 of the cover plate 53 takes the form of a pair of peripheral legs which are spaced-apart by a gap 59. The gap 59 allows the optical fibre to be observed through the shield 60. The body 51 of the shield 50 has a rear end 61 and opposed sides 63, 65 from which depends a peripheral skirt 67 which, in use, sits an the floor of the recess 3 of the package base 1 around the optical transceiver 20.

The cover plate 53 may, of course, cover the whole of the substrate 23 by forming the forward portion 57 as a continuous surface, i.e. by “plugging” the gap 59. Moreover, the peripheral skirt 67 may be seated on the ceramic insulator 37, rather than the floor of the recess 3, if the margin of the insulator 37 is sufficiently great.

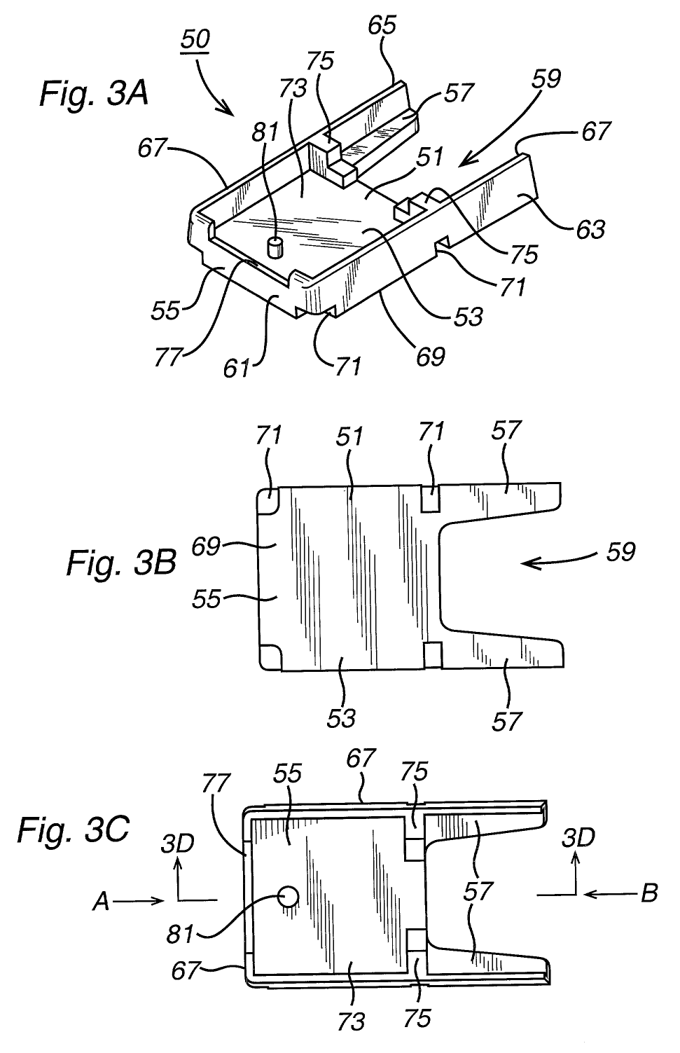

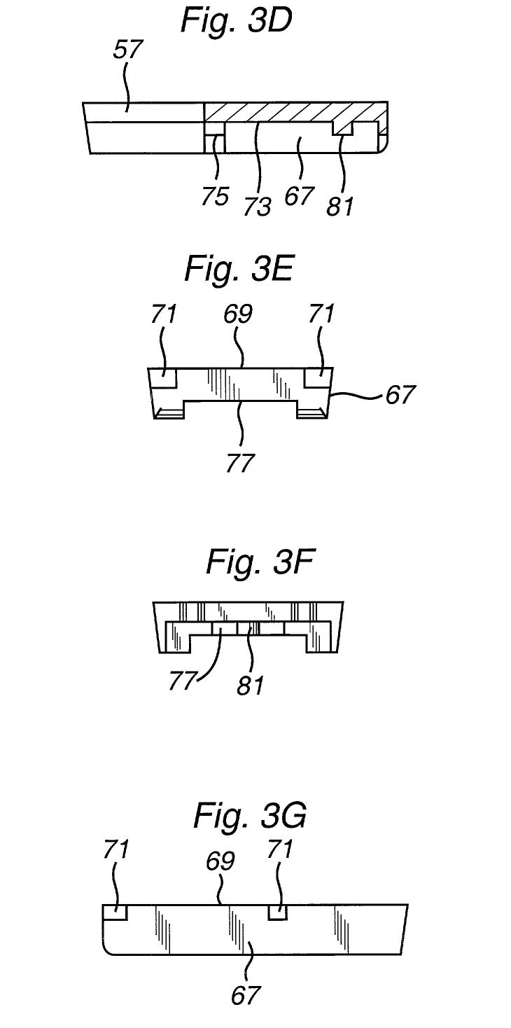

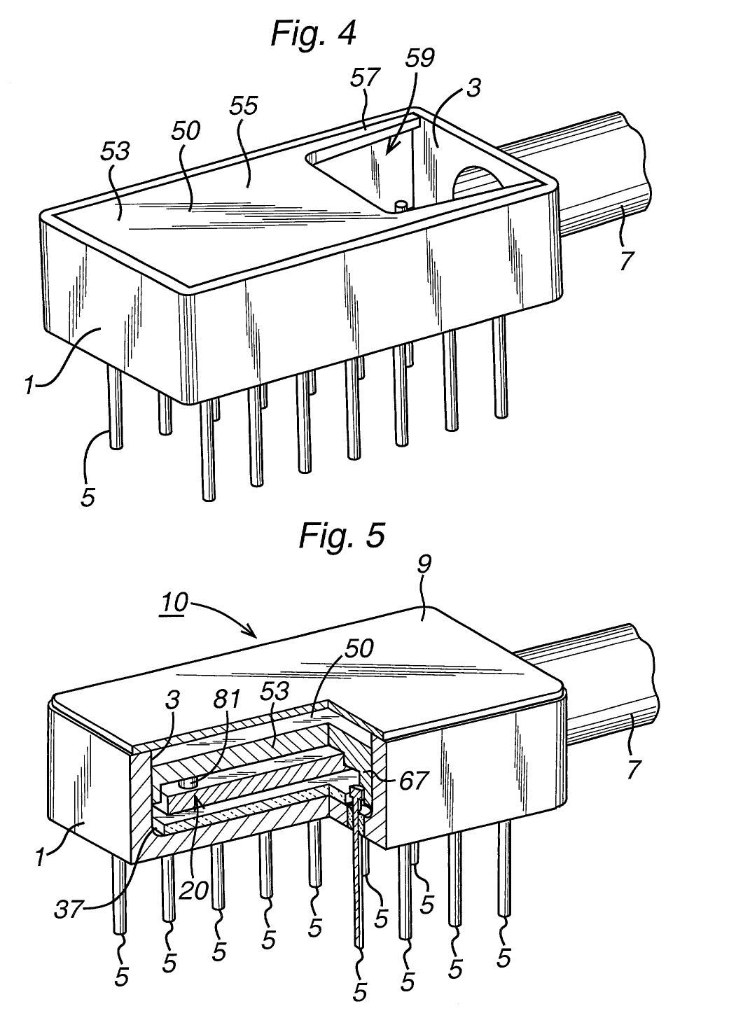

The shape and size of the periphery of the shield 50 is such that a close fit is formed between the shield 50 and the recess 3, as shown in FIG. 4. To ease the insertion of the shield 50 into the recess 3, the peripheral skirt 67 may taper inwardly, as shown in FIGS. 3E and 3F.

The sizing of the shield 50 and the recess 3 of the package base 1 may Fe such as to form an interference fit therebetween. Alternatively, or in addition, adhesive may be used to adhere the shield 50 to the recess 3 of the package base 1. As shown in FIGS. 3A. 35, 3F and 3G, the cover plate 53 of the shield 50 may have an upper surface 69 which is provided with a number of notches 71 into which an adhesive, such as an epoxy resin adhesive, can be disposed to adhere the shield 50 to the sides of the recess 3 of the package base 1.

On an underside 73 of the cover plate 53, proximate the junction between the rear and forward portions 55, 57, there is provided a pair of inwardly directed wall elements 75 having a step profile. The step profile allows the optical transceiver 20 to be disposed underneath the cover plate 53. For similar reasons, a cut-out 77 is formed in the peripheral skin 67 at the rear end 61.

As will be understood from FIGS. 3A, 3C, 3D, 3F and 5, an integrally formed post 81 depends from the underside 73 of the rear portion 55 of the cover plate 53 of the shield 50. The post 81 is so positioned and dimensioned that, when the shield 50 is seated in the recess 3 of the package base 1, the post 81 is located between the diodes 31, 33 on the optical transceiver 20, preferably making contact with the substrate upper surface 25. In this way, super-substrate stray light propagating along an optical axis extending from the laser diode 31 to the photodiode 33 is absorbed by the post 81.

The silicon substrate 23 is also optically conducting whereby stray light can propagate from the laser diode 31 to the photodiode 33 through the substrate 23. Accordingly, in a modified embodiment of the invention, the upper surface 25 of the substrate 23 may be provided with a recess between the diodes 31, 33 and the length of the light absorbing post 81 extended so that, in use, it extends into the recess. Thus, intra-substrate stray light is blocked by the post 81 in addition to super-substrate stray light.

The optical chip 20 may contain more than one opto-electronic component which needs shielding from optical cross-talk from the laser diode 31. Accordingly, in another embodiment of the invention a plurality of posts 81 are provided to be positioned between the laser diode 31 and each of the opto-electronic components to be shielded. The additional opto-electronic components may themselves be a light emitting diode and/or a further light sensitive diode and/or a monitor etc. Recesses may also be provided on the substrate upper surface 25 for the additional posts 81 to extend into to provide shielding against intra-substrate stray light.

The advantages of using the shield 50 include:

The manufacturing process is simplified due to the light absorbing post 81 forming an integral part of the shield 50, as compared to the prior art case where a separate isolation lid and post are used; and

The post 81 is more durable as it is not adhered to the substrate surface 25.

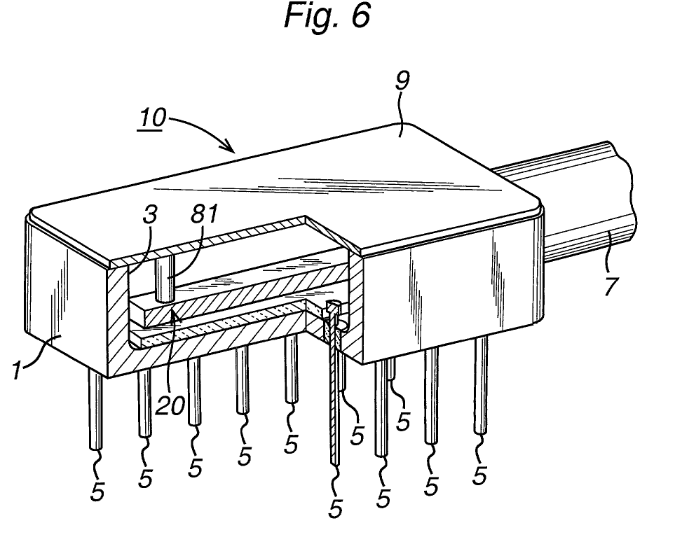

In a further embodiment shown in FIG. 6, the shield 50 is dispensed with and the post 81 is integrally formed with, and depends from, the lid 9. Similar advantages to those arising from use of the shield 50 result from this embodiment. Going one step further, the lid 9 could also be formed from the material of the shield 50.

In a yet further embodiment, the cover plate 53 of the shield 50 is constructed to cover the whole of the substrate 23 of the optical chip 20 (by “plugging” the gap 59) and the peripheral skirt 67 depends from each side of the cover plate 53 to encapsulate the substrate 23. The peripheral skirt 67 is fused to the ceramic insulator 37 to form a hermetic package for the optical chip. In this way, the optical chip 20 is protected Curing the assembly process and the lid of the normal KOVAR package 10 can be dispensed with.

It will be understood by the reader skilled in the art that the present invention is not restricted to the specific embodiments described with reference to the accompanying Figures of drawings but may be varied in many different ways within the scope of the appended claims. For instance, only the post 81 of the shield 50 may be formed from a light absorbing material. Moreover, the shield 50 need not necessarily be in a form which covers the substrate upper surface 25. The shield 50 may, for example, be located to one side of the optical chip 20, e.g. like a fence, with the post 81 extending across the substrate upper surface 25 between the laser diode 31 and the photodiode 33. Similarly, the post 81 may be integrally formed with, and depend from, a surface of the recess 3 of the package base 1 instead of the lid 9. Furthermore, the post 81 could take the form of a feature having a different shape or geometry. For instance, the post 81 may take the form of a wall element or the like Lastly, the invention is not restricted to optical transceivers but has application for any optical chip or optical circuit device where optical cross-talk needs reducing.

1. A package for receiving an optical chip having a light source to emit light and a circuit element whose performance is adversely affected by the incidence thereon of stray light from the light source, the package including a barrier element which is adapted to absorb light emitted by the light source and which is so dimensioned and arranged as to be positioned between the light source and the circuit element when the optical chip is received in the package.

2. A package according to claim 1 in which the optical chip has a substrate with a surface an which the light source and the circuit element are positioned, wherein the barrier element is so dimensioned and arranged as to be positioned on the substrate surface when the optical chip is received in the package.

3. A package according to claim 1 or 2 having a movable element which has a surface from which the barrier element depends.

4. A package according to claim 3, wherein the movable element is a detachable element of the package.

5. A package according to claim 3 or 4, wherein the movable element is an internal cover which covers at least a part of the surface of the optical chip when the optical chip is received in the package.

6. A package according to any one of claims 3 to 5, wherein the movable element is an outer lid.

7. A package according to any one of claims 1 to 6, wherein the barrier element is in the form of a post.

8. A package according to any one of claims 1 to 6, wherein the barrier element is in the form of an elongate wall.

9. A package according to any one of the preceding claims in which the optical chip has a substrate with a surface on which the light source and the circuit element are positioned, wherein the barrier element is sized to be received in a structural discontinuity in the substrate surface.

10. A package according to claim 9, wherein the barrier element is sized so that a first portion is received in the structural discontinuity and a second portion is located above the substrate surface.

11. A package according to any one of the preceding claims, wherein the barrier element is formed from a composition which contains carbon.

12. A package according to any one of the preceding claims, wherein the barrier element is formed from a composition which contains a plastics material.

13. A package according to claim 12, wherein the plastics material is a homopolymer, a copolymer or a blend of a thermoplastic polyester or a mixture thereof.

14. A package according to claim 13, wherein the thermoplastic polyester is poly(butylene terephthalate).

15. A package according to any one of the preceding claims including the optical chip.

16. A shield for reducing optical cross-talk in an optical circuit device having a light source to emit light and a circuit element whose performance is adversely affected by the incidence thereon of stray light from the light source, the shield having a body part which is adapted in use to be secured to the optical circuit device and a barrier part depending from the body part which is adapted to absorb light emitted by the light source, wherein the shield is so constructed and arranged that the barrier part is positioned between the light source and the circuit element when the body part is secured to the optical circuit device.

17. A shield according to claim 16, wherein the barrier part is in the form 5 of a post.

18. A shield according to claim 16, wherein the barrier part is in the form of an elongate wall.

19. A shield according to claim 16, 17 or 15, wherein the barrier part is formed from a composition which contains carbon.

20. A shield according to any one of claims 16 to 19, wherein the barrier part is formed from a composition which contains a plastics material.

21. A shield according to claim 20, wherein the plastics material is a homopolymer, a copolymer or a blend of a thermoplastic polyester or a mixture thereof.

22. A shield according to claim 21, wherein the thermoplastic polyester is poly(butylene terephthalate).

23. A shield according to any one of claims 16 to 22, wherein the body part is formed from the same material as the barrier part.

24. A shield according to any one of the preceding claims in which the light source and circuit element are located on a surface of a substrate, wherein the shield is so constructed and arranged that the barrier part is positioned on the substrate surface when the body part is secured to the optical circuit device.

25. A shield according to any one of claims 16 to 24 in which the light source and circuit element are located on a surface of a substrate, wherein the shield is so constructed and arranged that the barrier part is received in a structural discontinuity in the substrate surface when the body part is secured to the optical circuit device.

26. A shield according to claim 25 which is so constructed and arranged that a first portion of the barrier part is received in the structural discontinuity and a second portion is disposed above the substrate surface when the body part is secured to the optical circuit device.

27. In combination, an optical circuit device having an optical chip having a light source to emit light and a circuit element whose performance is adversely affected by the incidence thereon of stray light from the light source, and a shield according to any one of claims 16 to 26.

28. A combination according to claim 27 in which the optical circuit device has a package according to any one of claims 3 to 7 which receives the optical chip, wherein the shield takes the form of the movable element.
